(19) United States
(12) Patent Application Publication
(10) Pub. No.: US 2023/0215770 A1
(43) Pub. Date: Jul. 6, 2023

(54) SEMICONDUCTOR MANUFACTURING APPARATUS, INSPECTION APPARATUS, AND MANUFACTURING METHOD FOR SEMICONDUCTOR DEVICE

(71) Applicant: Fasford Technology Co., Ltd., Minami-Alps City (JP)

(72) Inventors: Hideharu KOBASHI, Minami-Alps (JP); Keita YAMAMOTO, Minami-Alps (JP); Akio MATSUZOE, Minami-Alps (JP)

(21) Appl. No.: 18/083,655

(22) Filed: Dec. 19, 2022

(30) Foreign Application Priority Data
Jan. 6, 2022 (JP) 2022-001331
Jan. 6, 2022 (JP) 2022-001332

(51) Int. Cl. H01L 21/66; H01L 21/67; H01L 21/677

(52) U.S. Cl. CPC H01L 22/12; H01L 22/24; H01L 21/67253; H01L 21/67132; H01L 21/67144; H01L 21/67712; H01L 23/544

(57) ABSTRACT

A semiconductor manufacturing apparatus includes an imaging device that images a die; a lighting device having a light source that is a point light source or a line light source; and a controller configured to apply a light beam to a part of the die by the light source to form a bright field area on the die, and repeat moving the bright field area at a predetermined pitch and imaging of the die to inspect an inside of the bright field area.

### Claim of Priority

The present application claims priority from Japanese Patent Application JP 2022-001331 filed on Jan. 6, 2022 and Japanese Patent Application JP 2022-001332 filed on Jan. 6, 2022, the content of which is hereby incorporated by reference into this application.

### BACKGROUND

The present disclosure relates to a semiconductor manufacturing apparatus, which is applicable to a die bonder that performs surface inspection of dies, for example.

The manufacturing process of a semiconductor device partially includes a process in which a semiconductor chip (in the following, referred to as a die) is mounted on a circuit board, a lead frame, or the like (in the following, referred to as a substrate) to assemble a package, and the process of assembling a package partially includes a process (dicing process) of dividing a semiconductor wafer (in the following, simply referred to as a wafer) into dies, and a die bonding process of mounting the divided die on a substrate. A semiconductor manufacturing apparatus used for the die bonding process is a die bonder and the like. At this time, in the die bonding process or a previous process, a dicing process, for example, cracks, scratches, and the like sometimes occur in a die (in the following, referred to as flaws).

### SUMMARY

An object of the present disclosure is to provide a technique that is capable of improving the detection accuracy of flaws. The other objects and novel features will be apparent from the description of the present specification and the accompanying drawings.

The following is the brief outline of a representative of the present disclosure.

That is, a semiconductor manufacturing apparatus includes: an imaging device that images a die; a lighting device having a light source that is a point light source or a line light source; and a controller configured to apply a light beam to a part of the die by the light source to form a bright field area on the die, and repeat moving the bright field area at a predetermined pitch and imaging of the die to inspect an inside of the bright field area.

According to the present disclosure, it is possible to improve the detection accuracy of flaws.

### BRIEF DESCRIPTION OF THE DRAWINGS

FIG. 1 is a schematic top view showing a configuration example of a die bonder according to a first embodiment;

FIG. 2 is a diagram showing a schematic configuration viewed from the direction arrow A in FIG. 1;

FIG. 3 is a block diagram showing the schematic configuration of a control system of the die bonder shown in FIG. 1;

FIG. 4 is a diagram showing a configuration example of the dark-field inspection system of a comparative example;

FIG. 5A is a diagram showing a captured image in the dark-field inspection system shown in FIG. 4;

FIG. 5B is a diagram showing a captured image in the dark-field inspection system shown in FIG. 4;

FIG. 6A is a diagram showing the principle of flaw detection using a bright field system;

FIG. 6B is a diagram showing the principle of flaw detection using a bright field system;

FIG. 6C is a diagram showing the principle of flaw detection using a bright field system;

FIG. 6D is a diagram showing a captured image in a bright-field inspection system;

FIG. 6E is a diagram showing a configuration example of the bright-field inspection system of the comparative example;

FIG. 7A is a diagram showing a configuration example of the bright-field inspection system of the comparative example;

FIG. 7B is a diagram showing a captured image shown in a bright field system in FIG. 7A;

FIG. 8A is a diagram showing that a shadow is formed in a recess by collimated light beams;

FIG. 8B is a diagram showing that a shadow is formed in a recess by a point light source;

FIG. 9 is a diagram showing that no shadow is formed in a recess in the case of using a surface light source;

FIG. 10A is a diagram showing a configuration example of a bright-field inspection system according to a first embodiment;

FIG. 10B is a diagram showing a captured image in a bright field system shown in FIG. 10A;

FIG. 11A is a diagram showing the case in which a point light source is moved in a bright-field inspection system shown in FIG. 10A;

FIG. 11B is a diagram illustrating the moving of a bright field area in the case of moving a point light source;

FIG. 11C is a diagram showing the case of moving a die in the bright-field inspection system shown in FIG. 10A;

FIG. 11D is a diagram showing the case of moving a camera in the bright-field inspection system shown in FIG. 10A;

FIG. 12 is a diagram illustrating overlaps between bright field areas;

FIG. 13 is a diagram showing dark-field inspection by the bright-field inspection system shown in FIG. 10A;

FIG. 14 is a diagram showing the disposition of a wafer recognition camera and a lighting device and the configuration of the lighting device;

FIG. 15 is a timing chart showing the timings of imaging by a wafer recognition camera and an image process by a controller;

FIG. 16 is a diagram showing the configuration of a coaxial illuminator having a diffuser for a surface emitting illuminator;

FIG. 17A is a diagram showing the configuration of a surface emitting illuminator according to a first exemplary modification of the first embodiment;

FIG. 17B is a diagram showing the configuration of a surface emitting illuminator according to a second exemplary modification of the first embodiment;

FIG. 18 is a diagram showing the configuration of a bright-field inspection system according to a third exemplary modification of the first embodiment;

FIG. 19A is a flowchart showing the operation of the bright-field inspection system according to the first embodiment;

FIG. 19B is a flowchart showing the operation of the bright-field inspection system according to a fourth exemplary modification of the first embodiment;

FIG. 20 is a diagram showing a captured image and brightness in the dark-field inspection system shown in FIG. 4;

FIG. 21 is a diagram showing a configuration example of the dark-field inspection system of a second embodiment;

FIG. 22A is a diagram showing an image imaging a die that is an inspection target in the case in which a lighting device moves at a position (a) shown in FIG. 21;

FIG. 22B is a diagram showing a captured image in the case in which the lighting device moves at a position (b) shown in FIG. 21;

FIG. 23 is a diagram showing the operation of a dark-field inspection system according to the first exemplary modification of the second embodiment;

FIG. 24A is a diagram showing the operation of a dark-field inspection system according to the second exemplary modification of the second embodiment;

FIG. 24B is a diagram showing the operation of the dark-field inspection system according to a third exemplary modification of the second embodiment;

FIG. 25 is a diagram showing the configuration and operation of a dark-field inspection system according to a fourth exemplary modification of the second embodiment;

FIG. 26A is a diagram showing a captured image in the case in which the lighting device moves at a position (a) shown in FIG. 25;

FIG. 26B is a diagram showing a captured image in the case in which the lighting device moves at a position (b) shown in FIG. 25;

FIG. 26C is a diagram showing a captured image in the case in which the lighting device moves at a position (c) shown in FIG. 25;

FIG. 26D is a diagram showing a captured image in the case in which the lighting device moves at a position (d) shown in FIG. 25;

FIG. 27 is a diagram showing the configuration and operation of the dark-field inspection system according to a fifth exemplary modification of the second embodiment; and

FIG. 28 is a diagram showing the configuration of a dark-field inspection system according to a sixth exemplary modification of the second embodiment.

### DESCRIPTION OF THE PREFERRED EMBODIMENTS

In the following, embodiments and exemplary modifications will be described with reference to the drawings. However, in the following description, the same components are designated with the same reference signs, and a duplicate description may be omitted. Note that in order to further clarify the description, the drawings may schematically show the width, thickness, shape, and the like of components, compared to the actual forms. However, this is merely an example, and does not limit the interpretation of the present disclosure.

### First Embodiment

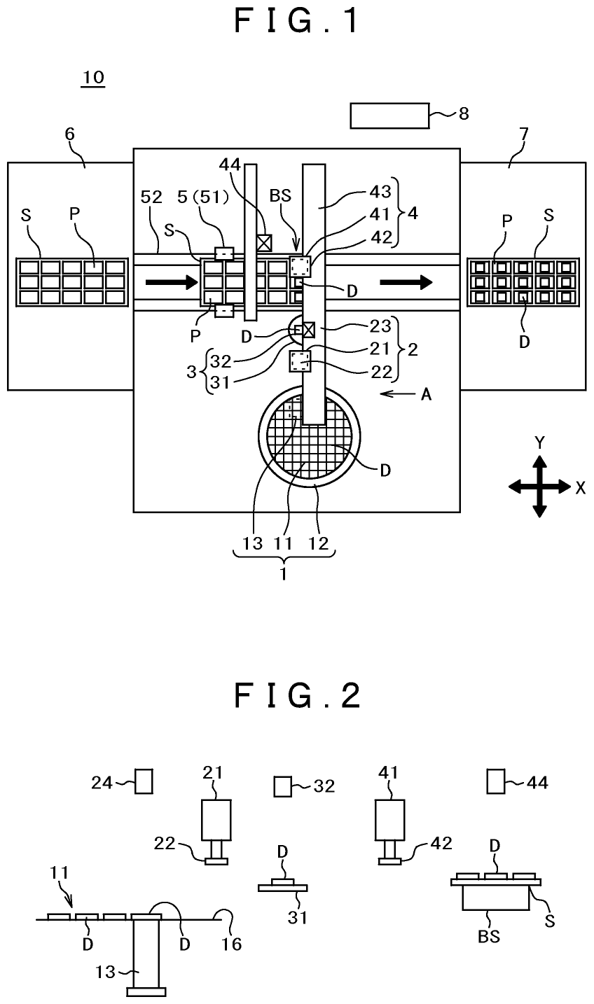

The configuration of the die bonder according to the present embodiment will be described with reference to FIGS. 1 and 2.

The die bonder 10 roughly has a die supply unit 1, a pickup unit 2, an intermediate stage unit 3, a bonding unit 4, a transfer unit 5, a substrate supply unit 6, a substrate unloader 7, and a control unit (a control device, a controller) 8 that monitors and controls the operation of each unit. A Y-axis direction is the longitudinal direction of the die bonder 10, and an X-axis direction is the lateral direction. The die supply unit 1 is disposed on the front side of the die bonder 10, and the bonding unit 4 is disposed on the back side. Here, on a substrate S, one or a plurality of product areas (in the following, referred to as a package area P), which finally becomes one package, is printed.

The die supply unit 1 has a wafer holding stage 12 that holds a wafer 11, and a push-up unit 13, denoted by a dotted line, that pushes up a die D from the wafer 11. The wafer holding stage 12 moves in the XY-direction by a drive unit, not shown, and moves a die D to be picked up at the position of the push-up unit 13. The push-up unit 13 moves in the vertical direction by a drive unit, not shown. The wafer 11 is adhered on dicing tape 16, and is divided into a plurality of dies D. The wafer 11 is held on a wafer ring, not shown. Between the wafer 11 and the dicing tape 16, an adhesive material in a film shape, which is referred to as a die attach film (DAF), is stuck.

The pickup unit 2 has a pickup head 21 that picks up the die D, a Y-drive unit 23 of the pickup head that moves the pickup head 21 in the Y-direction, drive units, not shown, that raise, lower, rotate, and move a collet 22 in the X-direction, and a wafer recognition camera 24 that recognizes the attitude of the die D on the wafer 11. The pickup head 21 has the collet 22 that adsorbs and holds the pushed-up die D at its tip end, and the pickup head 21 picks up the die D from the die supply unit 1, and places the die D on an intermediate stage 31. The pickup head 21 has the drive units, not shown, that raise and lower, rotate, and move the collet 22 in the X-direction.

The intermediate stage unit 3 has the intermediate stage 31 on which the die D is temporarily placed, and a stage recognition camera 32 that recognizes the die D on the intermediate stage 31.

The bonding unit 4 has a bonding head 41, a Y-drive unit 43, and a substrate recognition camera 44. The bonding head 41 includes a collet 42 that adsorbs and holds the die D at its tip end similarly to the pickup head 21. The Y-drive unit 43 moves the bonding head 41 in the Y-axis direction. The substrate recognition camera 44 images a recognition mark (not shown) at the position of the package area P on the substrate S, and recognizes a bonding position. The bonding unit 4 picks up the die D from the intermediate stage 31, bonds the die on the package area P on the substrate S, which is being transferred, or bonds a die being stacked on the die already having bonded in the package area P on the substrate S. With such a configuration, the bonding head 41 corrects the pickup position and the attitude based on the imaging data of the stage recognition camera 32, and picks up the die D from the intermediate stage 31. The bonding head 41 then bonds the die D in the package area P on the substrate or bonds the die D being stacked on the die already bonded in the package area P on the substrate S based on the imaging data of the substrate recognition camera 44.

The transfer unit 5 has a substrate transfer claw 51 that grips and transfers the substrate S, and a transfer lane 52 on which the substrate S is moved. The substrate S is moved by driving a nut, not shown, of the substrate transfer claw 51 provided on the transfer lane 52 using a ball screw provided along the transfer lane 52. With such a configuration, the substrate S is moved from the substrate supply unit 6 to the bonding position along the transfer lane 52, and after bonding, the substrate S is moved to the substrate unloader 7, and delivered to the substrate unloader 7.

The wafer recognition camera 24, the stage recognition camera 32, and the substrate recognition camera 44 are used with a lighting device, described later, for the surface inspection of the die D. The lighting device used for the surface inspection may be the same as a lighting device used for the attitude recognition of the die D and the like, or may be varied.

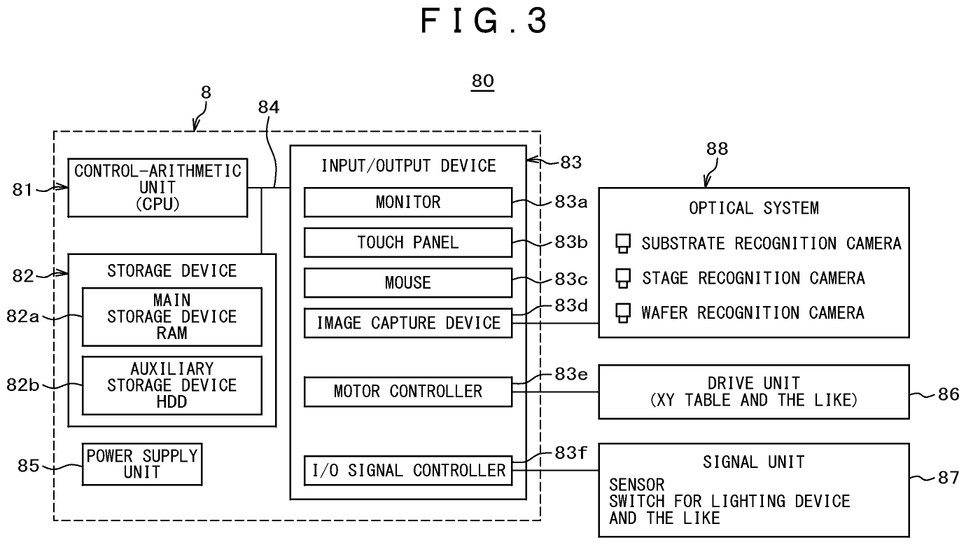

Next, the controller 8 will be described with reference to FIG. 3.

A control system 80 includes the controller 8, a drive unit 86, a signal unit 87, and an optical system 88. The controller 8 roughly has a control-arithmetic unit 81 mainly formed of a Central Processing Unit (CPU), a storage device 82, an input/output device 83, a bus line 84, and a power supply unit 85. The storage device 82 has a main storage device 82a formed of a Random Access Memory (RAM) that stores a process program and the like, and an auxiliary storage device 82b formed of a Hard Disk Drive (HDD), a Solid-State Drive (SSD), and the like that stores control data, image data, or the like necessary for control.

The input/output device 83 has a monitor 83a that displays a devise status, information, and the like, a touch panel 83b that inputs the instruction of an operator, a mouse 83c that operates the monitor 83a, and an image capture device 83d that captures image data from the optical system 88. The input/output device 83 has a motor controller 83e that controls the drive unit 86 such as the XY table (not shown) of the die supply unit 1, the ZY-drive shaft of a bonding head table, and the like, and an I/O signal controller 83f that captures or controls signals from the signal unit 87 including various sensors, switches controlling the brightness of a lighting device 26, described later, and the like, and volumes. The optical system 88 includes the wafer recognition camera 24, the stage recognition camera 32, and the substrate recognition camera 44. The control-arithmetic unit 81 captures necessary data through the bus line 84, performs computation to control the pickup head 21 and the like or to send information to the monitor 83a and the like.

The controller 8 saves image data imaged with the wafer recognition camera 24, the stage recognition camera 32, and the substrate recognition camera 44 through the image capture device on the storage device 82. The positioning of the die D and the package area P on the substrate S and the surface inspection of the die D and the substrate S are performed using the control-arithmetic unit 81 with software programmed based on the saves image data. The drive unit 86 is driven through the motor controller 83e with software based on the positions of the die D and the package area P on the substrate S calculated by the control-arithmetic unit 81. By this process, the die on the wafer is positioned and operated by the drive units of the pickup unit 2 and the bonding unit 4, and the die D is bonded on the package area P on the substrate S. The wafer recognition camera 24, the stage recognition camera 32, and the substrate recognition camera 44 for use convert light intensities or colors into numerical values. The wafer recognition camera 24, the stage recognition camera 32, and the substrate recognition camera 44 are also referred to as imaging devices.

Next, a die bonding process, which is a process for a manufacturing method for a semiconductor device using the die bonder 10, will be described. First, a wafer ring having a wafer mounted is prepared, and loaded into the die bonder 10 (process P1). The controller 8 places the wafer ring on the wafer holding stage 12, and transfers the wafer holding stage 12 to a reference position at which the die D is picked up (process P2). The substrate S is then prepared, and loaded into the die bonder 10 (process P3). The controller 8 places the substrate S on the transfer lane 52 at the substrate supply unit 6. The controller 8 moves the substrate transfer claw 51 that grips and transfers the substrate S to the bonding position (process P4).

Subsequently to the process P2, the controller 8 pitch-moves the wafer holding stage 12 on which the wafer 11 is placed at a predetermined pitch, holds the wafer holding stage 12 horizontally, and disposes a die D that is to be first picked up at the pickup position (process P5).

Subsequently to the process P5, the controller 8 images the principal surface (top surface) of the die D that is a pickup target using the wafer recognition camera 24, and calculates the amount of misregistration from the above-described pickup position of the die D that is a pickup target from the acquired image. The controller 8 moves the wafer holding stage 12 on which the wafer 11 is placed based on this amount of misregistration, and accurately disposes the die D that is a pickup target at the pickup position (process P6). The controller 8 then images the principal surface (top surface) of the die D that is a pickup target using the wafer recognition camera 24, and performs the surface inspection of the die D from the acquired image (process P7). Subsequently to the process P4, the controller 8 images the substrate S using the substrate recognition camera 44, and positions the substrate S based on the captured image (process P8). The controller 8 then images the substrate S using the substrate recognition camera 44, and performs the surface inspection of the package area P on the substrate S from the acquired image (process P9).

Subsequently to the P8 process, the controller 8 picks up the die D from the dicing tape 16 using the pickup head 21 including the collet 22, and places the die D on the intermediate stage 31 (process P10). After that, according to the similar procedures, the die D is peeled off one by one from the dicing tape 16. Upon completion of the pickup of all the dies D except detectives, the dicing tape 16, the wafer ring, and the like, which hold these dies D with the outer edge of the wafer 11, are unloaded.

Subsequently to the process P10, the controller 8 images the die D placed on the intermediate stage 31 to detect the displacement of the attitude of the die D using the stage recognition camera 32. In the case in which the displacement of the attitude is present, the controller 8 drives the intermediate stage 31 on a plane parallel with a mounting surface having a mounting position using the drive unit (not shown) provided on the intermediate stage 31 to correct the displacement of the attitude (process P11). The controller 8 then images the die D placed on the intermediate stage 31 using the stage recognition camera 32, and performs the surface inspection of the die D from the acquired image (process P12).

Subsequently to the P12 process, the controller 8 picks up the die D from the intermediate stage 31 using the bonding head 41 including the collet 42, and bonds the die D to the package area P on the substrate S or to a die already bonded in the package area P on the substrate S (process P13). Subsequently to the P13 process, after bonding the die

D, the controller 8 images the die D and the substrate S using the substrate recognition camera 44 for inspection whether to accurately achieve the bonding position (process P14). At this time, the center of the die and the center of the tab are found to inspect whether the relative position is correct. The controller 8 then images the die D and the substrate S using the substrate recognition camera 44, and performs the surface inspection of the die D and the substrate S from the acquired image (process P15). After that, according to the similar procedures, the die D is bonded one by one in the package area P on the substrate S. Upon completion of bonding to one substrate, the substrate S is moved to the substrate unloader 7 using the substrate transfer claw 51, and the substrate S is delivered to the substrate unloader 7 (process P16). The substrate S is then unloaded from the die bonder 10 (process P17).

As described above, the die D is mounted on the substrate S through the die attach film, and unloaded from the die bonder. After that, the die D is electrically connected to the electrode of the substrate S through an Au wire in a wire bonding process. In the case of fabricating a stacked package, subsequently, the substrate S on which the die D is mounted is loaded into the die bonder, and a second die D is stacked on the die D mounted on the substrate S through a die attach film. After the second die D is unloaded from the die bonder, the second die D is electrically connected to the electrode of the substrate S through an Au wire in the wire bonding process. The second die D and subsequent dies D are peeled off from the dicing tape 16 by the method described above, transferred to bonding positions, and stacked on the die D. After the process is repeated at a predetermined number of times, the substrate S is transferred to a molding process, pluralities of dies D and Au wires are sealed with a mold resin (not shown), and thus a stacked package is completed.

Although the surface inspection of flaws may be performed at least one site at the die supply unit 1, the intermediate stage unit 3, and the bonding unit 4 where die position recognition is performed, more preferably, surface inspection is performed at all the sites. When surface inspection is performed at the die supply unit 1, flaws can be detected in an early stage. When surface inspection is performed at the intermediate stage unit 3, a flaw, which has failed to be detected at the die supply unit 1, or a flaw made after a pickup process (a flaw, which has not become seen before the die bonding process) can be detected before bonding. When surface inspection is performed at the bonding unit 4, a flaw, which has failed to be detected at the die supply unit 1 and the intermediate stage unit 3 (a flaw, which has not become seen before the die bonding process) or a flaw made after the die bonding process can be detected before bonding for stacking the subsequent die or before ejecting the substrate. In order to more clearly define an illuminator for surface inspection according to the present embodiment, problems in the illuminator to detect flaws will be described.

In the case of designing an inspection function for flaws on a captured image using a camera, its illumination configuration includes a dark field method, which “darkens the background and brightens an object to be viewed,” and a bright field method, which “brightens the background and darkens an object to be viewed”.

(1) Dark Field Inspection System

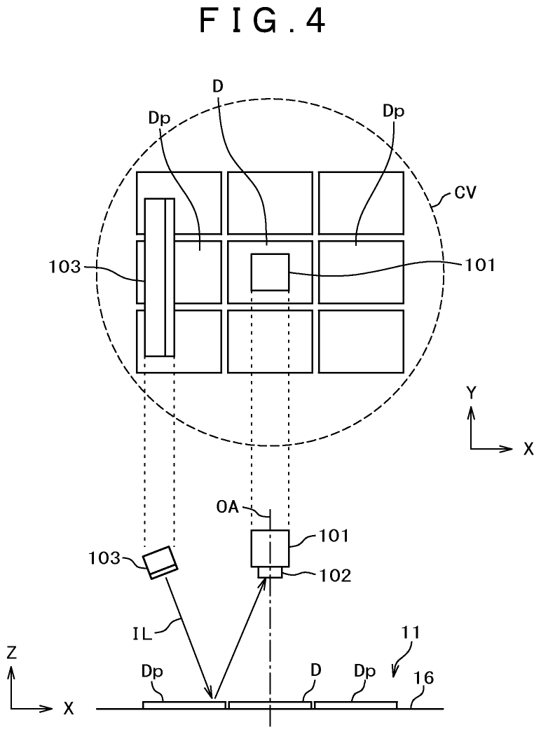

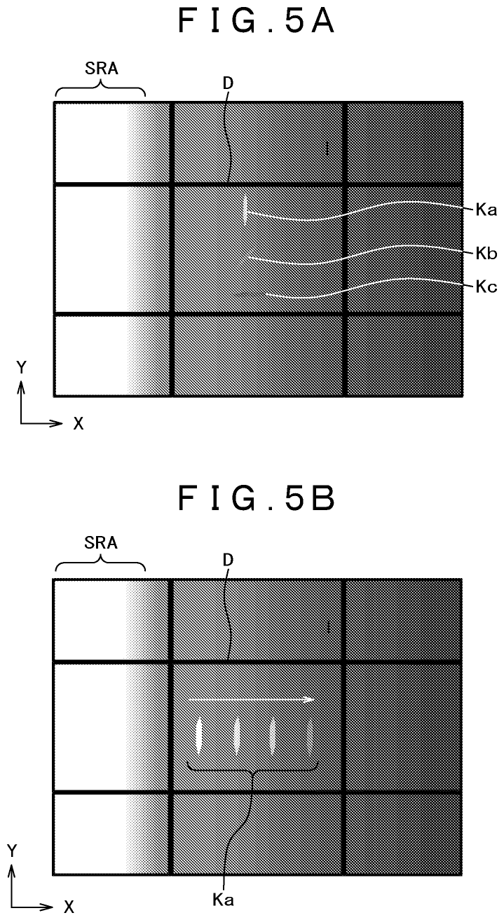

A dark-field inspection system using the dark field method will be described with reference to FIGS. 4, 5A, and 5B.

As shown in FIG. 4, a camera 101 attached with a lens 102 is disposed above the surface of a die D that is an inspection target. A visual field CV of the camera 101 includes a die D that is an inspection target and some or all surrounding dies Dp adjacent to the die D. A lighting device 103 is an oblique light illuminator such as an oblique light bar, and applies an illumination light beam IL to near the outer side of the die D that is an inspection target at a predetermined angle to an optical axis OA. Here, the illumination light beam IL is applied to the die Dp adjacent on the left side of the die D. The light-emitting face of the lighting device 103 extends in the Y-axis direction. The application direction of the illumination light beam IL in the horizontal direction is the X-axis direction.

The surface inspection (dark-field inspection) in the dark-field inspection system is performed in an area other than a specular reflection area SRA derived from the installation position of an oblique light bar illuminator. Here, the specular reflection area SRA is a specular reflection image of illumination reflected in the surface of Dip the die D and the like exhibiting specular reflection properties. As shown in FIG. 5A, the specular reflection area SRA has a rectangular shape having a length in the Y-axis direction longer than a length in the X-axis direction. The specular reflection area SRA is formed in the die Dp adjacent on the left side of the die D that is an inspection target. In dark-field inspection, a flaw is visualized by reflecting light on the side surface (in the inside) of a micro flaw. In the case in which a flaw such as a crack continuously and linearly occurs, its side surface also continues, and the flaw is visualized, the visualization depending on the application direction of the illumination light beam IL. Therefore, in the horizontal direction, the illumination light beam IL is applied from the direction different from the direction in which the flaw extends, and thus light is applied to the side surface.

As shown in FIG. 5A, in the horizontal direction, when the illumination light beam IL is applied from a direction (X-axis direction) perpendicular to a direction in which a flaw Ka extend (Y-axis direction), the light can be efficiently reflected, the flaw Ka is brightened and thus seen (the flaw Ka is recognizable). On the other hand, in the horizontal direction, when light is applied from a direction in parallel with a direction in which a flaw Kc extend (X-axis direction), the light is not efficiently applied to the side surface, the flaw Kc is darkened and thus not seen (the flaw Kc fails to be recognized). Note that a flaw Kb, which extends along a direction having components both in the X-axis direction and in the Y-axis direction, is difficult to be seen (the flaw Kb is difficult to be recognized). That is, in the dark-field inspection system shown in FIG. 4, the detection sensitivity of a flaw varies depending on the direction in which a flaw extends. Consequently, a detectable flaw is affected by the application direction of the illumination light beam IL, and a restriction is imposed on a detectable flaw.

As shown in FIG. 5B, although flaws Ka extend along the Y-axis direction are recognizable, the flaws Ka are gradually darker toward the direction of an arrow (X-axis direction). That is, the detection sensitivity greatly varies due to the relative positional relationship from the specular reflection area SRA.

(2) Bright Field Inspection System (Telecentric Lens)

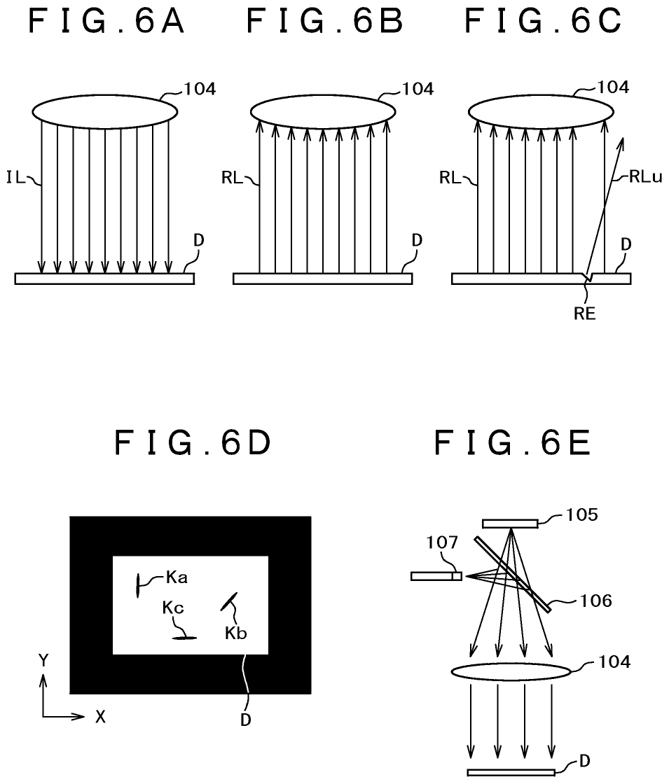

A bright-field inspection system using the bright field method will be described with reference to FIGS. 6A to 6E.

Since the dark-field inspection system has problems described above, a bright-field inspection system is often used in surface inspection. The bright-field inspection system is a system in which illumination light beams IL, which are collimated light beams, are applied to the surface of a subject having a flat surface and specular reflection properties (the surface of the die D), reflected light beams RL in specular reflection follow the same trace as the illumination light beams IL and are focused on a lens 104, and brighten the surface of the subject. As the traces of the illumination light beams IL shown in FIG. 6A, collimated light beams are applied to the surface of the die D. As the traces of the reflected light beams RL shown in FIG. 6B, the applied collimated light beams are reflected off the surface of the die D, and the reflected light beams RL are also collimated light beams. As reflected light beams shown in FIG. 6C, in the case in which a recess RE occurs due to a flaw and the like on the flat surface of the subject, since a reflected light beam RLu of the recess RE is not recovered by the lens 104, the recess RE is imaged as a dark area, and this dark area is detected as a flaw by an image process.

As shown in FIG. 6D, a flaw Ka extending along the Y-axis direction becomes darker and seen (the flaw Ka is recognizable). A flaw Kb extending along the direction having components both in the X-axis direction and the Y-axis direction also becomes darker and seen (the flaw Kb is recognizable). A flaw Kc extending along the X-axis direction also becomes darker and seen (the flaw Kc is recognizable). That is, the bright-field inspection system has no directionality for the detectable flaw, and can also detect flaws extending in given directions. The sensitivity does not vary due to the relative positional relationship of illumination. For example, in the case of a coaxial illuminator, since a recess RE due to a flaw on the surface of a wafer can be detected, in the bright field method, the application direction of illumination and the direction of a flaw do not have to be considered. Since areas other than flaws are made fully bright, mask patterns transferred to the die D are not prone to be affected.

However, since in the bright-field inspection system, collimated light beams are applied to the subject, and collimated light beams have to be limited for use when the reflected light beams are collected using a lens, a telecentric lens has to be used for the lens. As shown in FIG. 6E, using a coaxial illuminator in which a half mirror 106 is installed on the side of an image forming face 105 of the lens 104 and a light source 107 is installed at a focal position, collimated light beams are applied to the die D, and the reflected light beams are focused by the lens 104. In regard to the telecentric lens, its lens diameter has to be increased more than a necessary visual field size. A lens having a large diameter has large restrictions on the space and weight, leading to considerably high costs.

(3) Bright Field Inspection System (Macro Lens)

In the recent situation where cameras have become increasingly pixel-intensive, it is possible to achieve a wide visual field while maintaining high-definition pixel resolution. For this reason, a method in which a wide area is inspected in a batch using a macro lens, which is a non-telecentric lens, and the travel of a camera in the visual field is reduced to speed up the inspection process. Here, the macro lens has a visual field wider than its lens diameter.

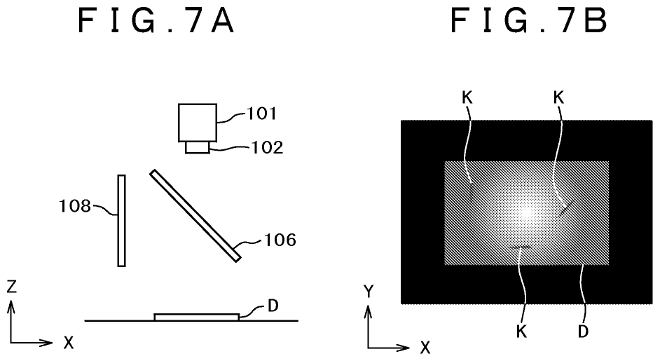

In order to obtain such a wide visual field, a high pixel camera and a macro lens are used. However, it is not possible to perform bright field appearance inspection by collimated light beam application. This will be described with reference to FIGS. 7A and 7B.

In a system having a main purpose of recognizing the attitude of the die D and the like to perform alignment, as shown in FIG. 7A, a surface emitting coaxial illuminator is installed in which a macro lens is used for the lens 102 using a surface light source 108 placed on the object (die D) side from the lens 102, and the entire surface of the die D is uniformly illuminated. Since the trace of the focused light in the macro lens, the light source of the coaxial illuminator has to be a surface emitting light source.

In the case of the surface emitting coaxial illuminator, even though a light beam from directly above a flaw that is an inspection target is reflected to anywhere other than the directly above direction, the incident angle of the illumination light beam to the flaw has a certain range, a light beam at any incident angle is reflected directly above, and as a result, the area of the flaw also becomes bright. This is because the light emission surface of the surface emitting coaxial illuminator is wide, having the nature of dome illumination. That is, since the surface emitting coaxial illuminator has the nature of dome illumination, no shadow is produced at the order of slight irregularities that occur due to a flaw and the like, the flaw is hidden in the bright area. Consequently, the dark field method has to be used for the surface inspection of a flaw and the like. In the surface emitting coaxial illuminator, even though a lens is disposed between the surface emitting illuminator and the half mirror to forcedly provide collimated light beams, as shown in FIG. 7B, the center becomes brighter and the periphery darker, and a bright field of uniform brightness fails to be obtained.

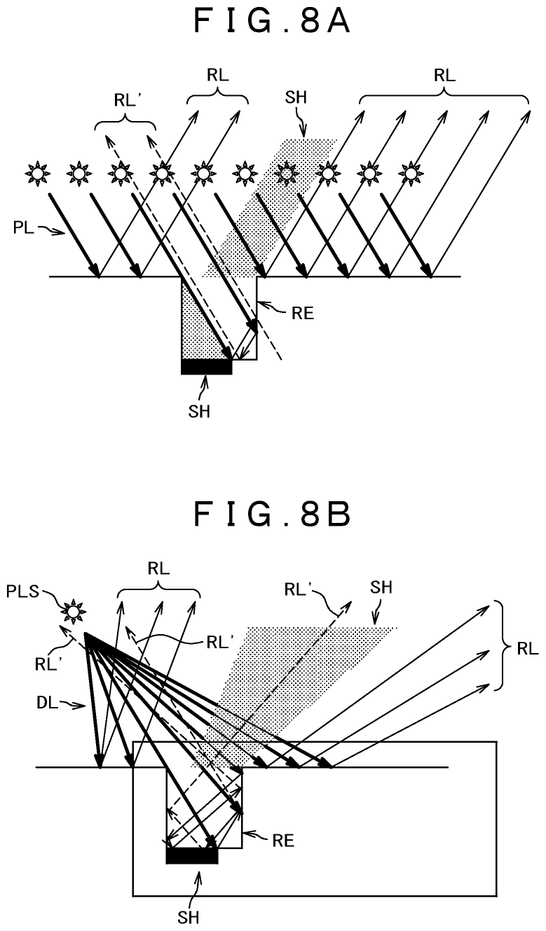

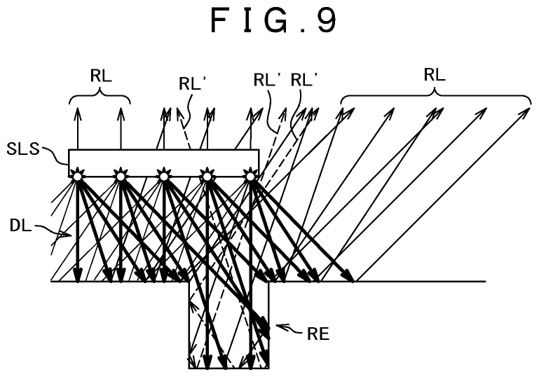

The principle of the bright-field inspection system of the present embodiment will be described with reference to FIGS. 8A, 8B, and 9.

The bright field method (bright field optical system) is constituted of three schemes (functions) below.
(A) A function to bring up shadows of flaws and the like having irregularities.
(B) A function to brighten surroundings in order to find shadows.
(C) A function to uniformly brighten the entire surface in order to secure the inspection area.

The therefore, generally, the application and focus of collimated light beams are necessary. As shown in FIG. 8A, collimated light beams PL obliquely entered to a flat surface (plane) are specularly reflected off the plane, and their reflected light beams RL (upward arrows depicted by solid lines) are observable. Since a recess RE is not a plane, no reflected light beam RL to be collimated light beams exist. Instead, the collimated light beams PL obliquely entered are reflected off the recess RE, and their reflected light beams RL′ (upward arrows depicted by dotted lines) travel in the direction opposite to the reflected light beam RL, for example, which are unobservable. That is, a shadow SH of the recess RE can be generated with the collimated light beams PL.

As shown in FIG. 8B, radial light beams DL, from a point light source PLS, obliquely entered to a plane are specularly reflected off the plane, and their reflected light beams RL (upward arrows depicted by solid lines) are observable. Since a recess RE is not a plane, no reflected light beam RL to be collimated light beams exists. Instead, the radial light beams DL obliquely entered are reflected off the recess RE, and their reflected light beams RL′ (upward arrows depicted by dotted lines) travel in the direction opposite to the reflected light beam RL, for example, which are unobservable. The reflected light beams

RL' traveling in the same direction as the reflected light beams RL are a few. That is, the shadow SH of the recess RE can also be generated by the point light source PLS (radial light beams).

However, as shown in FIG. 9, reflected light beams RL (upward arrows depicted by solid lines) in which radial light beams DL from a surface light source SLS, which are entered to a plane and specularly reflected off the plane are mixed with reflected light beams RL′ (upward arrows depicted by dotted lines) in which radial light beams DL, which are entered to a recess RE, are reflected off the recess RE, and no shadow is observed. That is, the surface light source SLS (radial light beams) fails to generate shadows in the recess RE.

The considering the functions (A) and (B) alone of the bright field method, the collimated light beams are recognizable rather a point light source or a line light source. In regard to the perfect collimated light beams, when observation is made from a certain point of a subject, the light source appears as a point light source. Even though the observation position of the subject is changed, a direction in which light beams come (light source direction) does not change at all. It should be noted here that in order to generate shadows of the recess due to a flaw and the like, light source beams do not have to be necessarily collimated, and rather, the light source only has to be a point light source or a line light source.

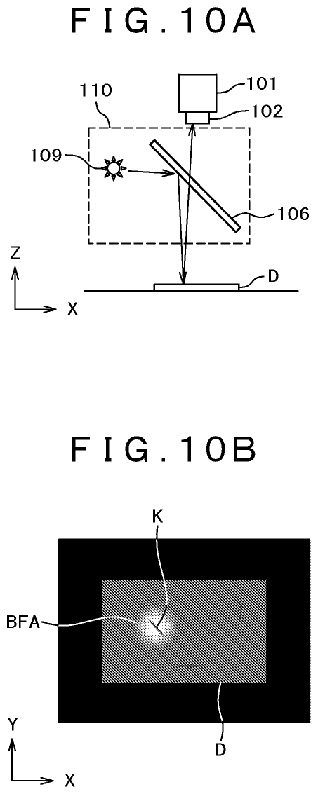

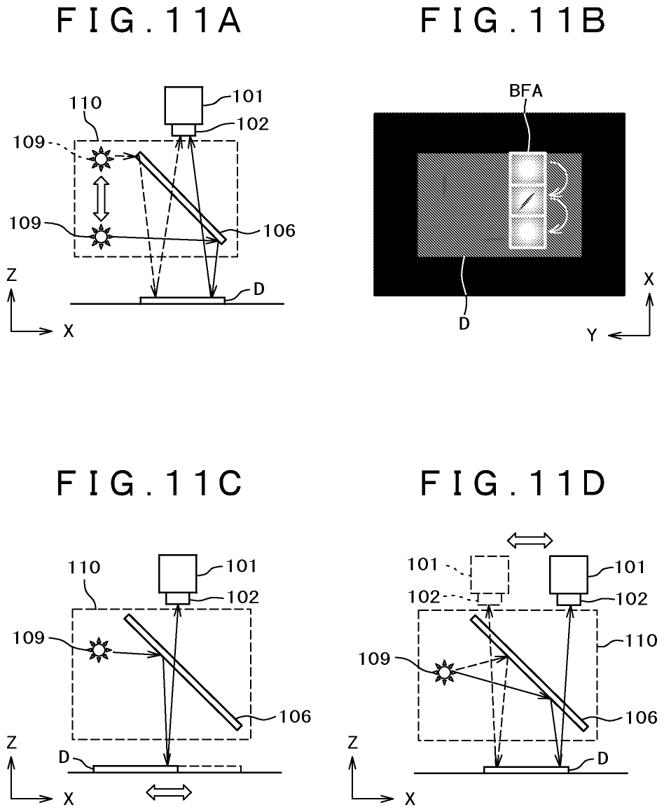

A bright-field inspection system using a point light source according to the present embodiment will be described with reference to FIG. 10A, FIG. 10B, and FIGS. 11A to 11D.

In the bright-field inspection system according to the present embodiment, for example, a macro lens is used for the lens 102 attached to the camera 101 as an imaging device. As shown in FIG. 10A, a lighting device 110 is installed between the lens 102 and the die D. The lighting device 110 is a point light source coaxial illuminator (coaxial epi-illuminator) constituted of the half mirror 106 and a point light source 109. In the case in which the camera 101 images the surface of the die D, which is a plane having the nature of specular reflection, as shown in FIG. 10B, a bright field area BFA like a spot is generated. Areas on the die D other than the bright field area BFA are dark field areas. The bright field area BFA has a nearly circular shape, and is an area smaller than the size of the die D in a plane. That is, a plurality of bright field areas BFA covers the entire surface of the die D. The entire surface of the die D is covered by at least two bright field areas BFA each in the X-axis direction and in the Y-axis direction. When a flaw K exists in the bright field area BFA, surface inspection (bright field inspection) according to the bright field method is feasible in which the flaw K is dark, and the surroundings of the flaw K are bright.

The point light source fails to implement the function

(C) of the bright field method. Therefore, as shown in FIG. 11A, the point light source 109 is moved in a direction indicated by an arrow (vertical direction). Thus, as shown in FIG. 11B, the bright field area BFA moves. The point light source 109 is moved at a predetermined pitch and the camera 101 images the die D, which are repeated, and the bright field area BFA alone is inspected. Accordingly, it is possible to subject the entire die D to bright field inspection.

In the bright-field inspection system shown in FIG. 11A, since moving the position of the bright field area BFA is performed, the point light source 109 is controlled to be moved. However, moving the position of the bright field area BFA is not limited to this. For example, as shown in FIG. 11C, the die D that is a subject may be controlled to be moved, or as shown in FIG. 11D, the camera 101 may be controlled to be moved. Note that as shown in FIG. 11C, in the case of moving the die D, the point light source 109 may be fixed to a position that is not included in the visual field of the camera 101, without using the half mirror 106. The point light source 109 shown in FIGS. 11A, 11C, and 11D may be a line light source.

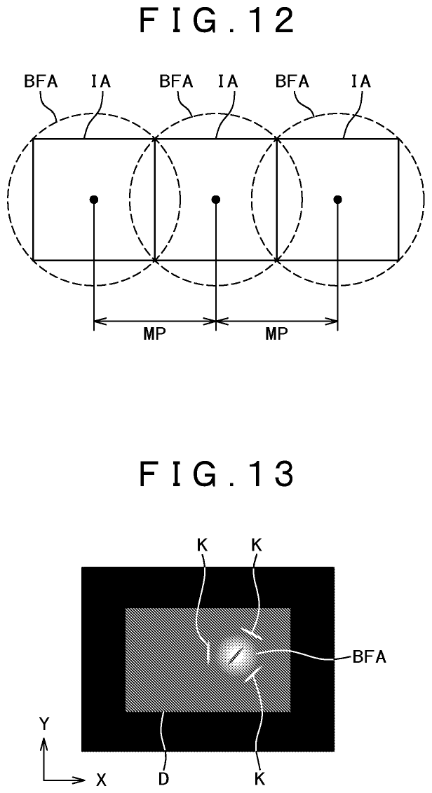

The bright field area BFA will be described with reference to FIG. 12.

In the case of setting an inspection area IA on the surface of the die D in a rectangular shape, since the bright field area BFA on the surface of the die D is a circular shape, the inspection area IA is set in the bright field area BFA, and the bright field area BFA is overlapped for moving. In the case in which the bright field area BFA is sufficiently bright to a threshold, which is no problem. However, in the case of the point light source, in regard to the uniformity of lightness of the bright field area BFA, the inspection area IA on the surface of the die D is sometimes inferior to the telecentric lens system. In the case in which there is the influence of variations in lightness due to the position inside the bright field area BFA (coordinates), a moving pitch MP of the point light source and the inspection area IA may be adjusted to increase the amount of overlap of the bright field area BFA for improving uniformity.

The note that in some cases, in the surroundings of the bright field area BFA illuminated with a spot, an area sometimes occurs in which an area to which surface inspection (dark-field inspection) is feasible by a high-sensitive dark field method. the dark-field inspection using this will be described with reference to FIG. 13.

To the bright field area BFA, a flaw K extending in the tangent direction of the circumference of concentric circles is visualized. When viewed from a fixed position, it is made possible to find a flaw extending in a given direction even in dark-field inspection according to the moving of the bright field area BFA. Thus, it is also possible to solve a problem of uniformity of detection sensitivity depending on the extending direction of a flaw in the dark-field inspection system described above. It is possible to detect a flaw having a considerably narrow width of a recess (the width is below one to two pixels), such as a flaw that causes vague irregularities, including a flaw having joined surface with crazing (fine cracks), for example. In the bright field inspection, the image of a shadow of a flaw having vague irregularities fades, which is difficult to detect.

The dark-field inspection by the surroundings of the bright field area BFA and the bright field inspection by the bright field area BFA may be processed in parallel. Accordingly, it is possible to simultaneously detect a flaw having vague irregularities, which is hard for bright field inspection, and a pit-like flaw and the like including scratches, which are hard for typical dark-field inspection, and it is possible to implement a highly sensitive inspection system.

Nowadays, speeding up of a camera (CMOS camera) using a Complementary Metal Oxide Semiconductor (CMOS) image sensor is advancing, and for example, even a camera with a pixel number of 5 M has a frame rate of 100 or more. When a Region of Interest (ROI) process (partial capture process) is added to this, the frame rate possibly exceeds 1,000. even though captures with divided areas are repeated, it takes less time for captures. Consequently, in the case of using a CMOS camera for the camera 101, even though imaging the bright field area BFA illuminated with a spot is repeated, it takes less time necessary for captures.

Nowadays, CMOS cameras transition to back-illuminated sensors, whose sensitivity is dramatically improved. Thus, since exposure time can also be shortened, it takes less time even for multiplex captures. In the case in which high-speed processing is necessary, preferably, a CMOS camera capable of high-speed imaging is used. Note that the imaging device according to the present embodiment is not limited to the CMOS camera, which may be a camera using a Charge Coupled Devices (CCD) image sensor, for example.

Since the illuminator using the point light source coaxial illuminator views the specular reflection area, its reflectance is high, and it is possible to achieve imaging for a shorter exposure time than the dark field method.

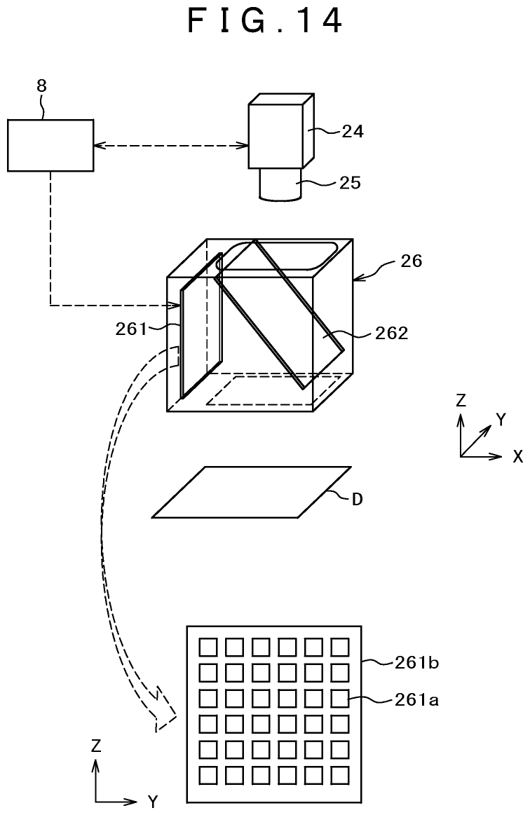

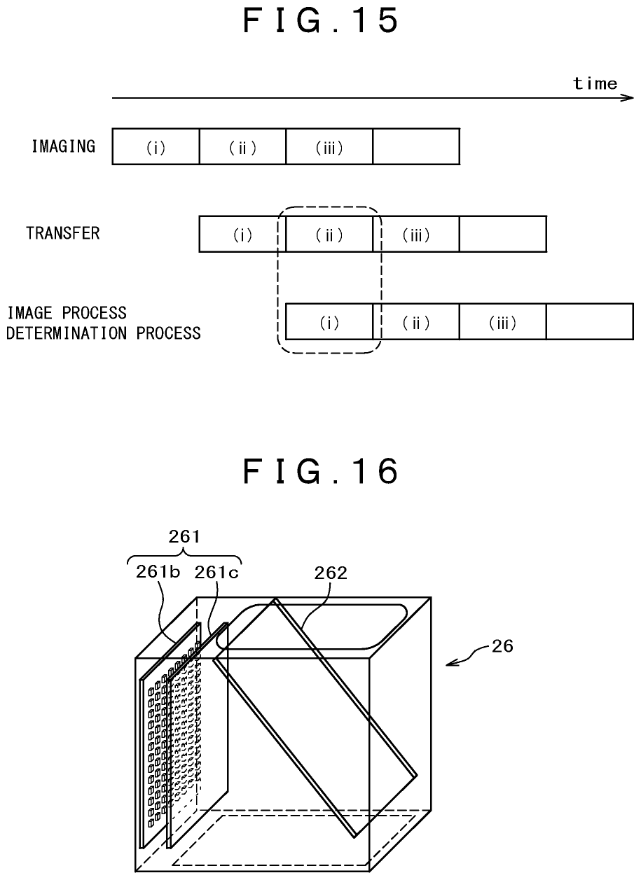

A specific example of the bright-field inspection system shown in FIG. 10A will be described, taking an example of the optical system of the pickup unit 2 according to the present embodiment with reference to FIGS. 14 and 15.

As shown in FIG. 14, the wafer recognition camera 24 is attached with an objective lens 25 formed of a macro lens, and the principal surface of the die D is imaged through this objective lens 25. Between the objective lens 25 and the die D on a line connecting the wafer recognition camera 24 to the die D, the lighting device 26 including a surface emitting illuminator (light source) 261 and a half mirror (semi-transmissive mirror) 262 its inside is disposed. Application light beams from the surface emitting illuminator 261 are reflected by the half mirror 262 at the optical axis the same as the wafer recognition camera 24, and are applied to the die D. The scattered light beams applied to the die D at the optical axis the same as the wafer recognition camera 24 are reflected off the die D, and the specularly reflected light beams of the scattered light beams are transmitted through the half mirror 262, and reaches the wafer recognition camera 24 to form an image of the die D. That is, the lighting device 26 has a function of the coaxial epi-illuminator (coaxial illuminator).

The surface emitting illuminator 261 in the lighting device 26 is a surface emitting LED light source, and includes an LED substrate 261b having a plurality of LEDs 261a as point light sources arrayed on a plane in a grid shape. The LEDs 261a are individually formed to turn on (ON) and turn off (OFF). That is, a part of the surface emitting illuminator 261 is sequentially turned on to move the light-emitting position.

At the time of surface inspection, the controller 8 is configured such that the LEDs 261a of the lighting device 26 are individually and sequentially turned on to form a point light source is formed as though the point light source is moved. The controller 8 is configured such that at the time of alignment, all the LEDs 261a of the lighting device 26 are turned on. Note that at the time of surface inspection, the controller 8 may be configured such that the LED 261a is sequentially turned on at every column or every row to form a line light source for moving the line light source.

Since illumination and imaging are repeated while moving the ROI (the bright field area BFA, the inspection area IA), transfer from the wafer recognition camera 24 to the controller 8 can be performed at every ROI. Thus, as shown in FIG. 15, after finishing the transfer of image data of the first ROI (i), the image process for the first ROI (i) can be performed during the transfer of the subsequent ROI (ii). That is, image data transfer from the wafer recognition camera 24 to the controller 8 and an image process and a determination process in the controller 8 can be performed in parallel with each other.

Although the wavelength of the light source of the lighting device 26 is not limited, in the case in which the lighting device 26 is specialized for surface inspection, preferably, a short wavelength light source of blue, violet, ultraviolet, and the like is used.

In the case in which the lightness stability of the bright field area is inferior to the bright-field inspection system of the telecentric lens more or less, the controller 8 may be configured in which an edge detection filter such as a differential filter or a second differential filter is used in the image process, a high-pass process is performed as signals for the difference of tonal light and shade, and fluctuations in tonal light and shade are not prone to be affected.

The optical system of the pickup unit 2 (the wafer recognition camera 24 and its lighting device 26) has been described. The optical system of the intermediate stage unit 3 (the stage recognition camera 32 and its lighting device) and the optical system of the bonding unit 4 (the substrate recognition camera 44 and its lighting device) also have similar configurations.

According to the present embodiment, one or a plurality of effects below can be obtained.
(1) Inspection is performed by the bright field method, and thus it is possible to reduce the uniformity of detection sensitivity due to the extending direction of a flaw. Accordingly, it is possible to improve the detection accuracy of flaws.
(2) Inspection is performed by the bright field method, and thus it is possible to reduce the uniformity of detection sensitivity due to the relative positional relationship from the specular reflection area. Accordingly, it is possible to improve the detection accuracy of flaws.
(3) In the case of using a macro lens, it is possible to achieve a wide visual field.
(4) Since the coaxial illuminator is used in the bright-field inspection system, it is possible to reduce the influence of the circuit patterns of the die brought up by the oblique light illuminator.
(5) Since it is possible to improve the detection accuracy of flaws, it is possible to improve the yields of a product assembled by the die bonder.

### Exemplary Modifications of First Embodiment

In the following, some representative exemplary modifications of the present embodiment will be described. In the description of the exemplary modifications below, it is assumed that components having similar configurations and functions as ones described in the present embodiment are designated with similar reference signs of the embodiment described above. In the description of these components, within a scope technically consistent, the description of the embodiment is to be appropriately incorporated by reference. A part of the embodiment and all or some of a plurality of exemplary modifications are to be appropriately incorporated within a scope technically consistent.

First Exemplary Modification

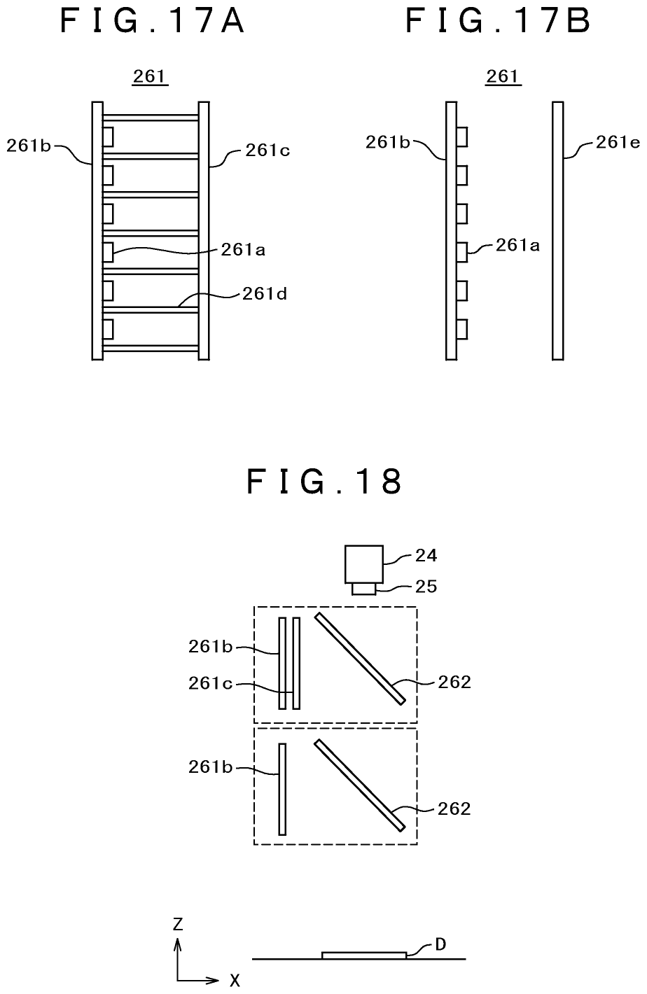

A coaxial illuminator according to a first exemplary modification will be described with reference to FIGS. 16 and 17A.

As shown in FIG. 16, in an alignment coaxial illuminator, a diffuser 261c is sometimes installed between an LED substrate 261b and a half mirror 262. Here, the diffuser is a colored filter in translucent white and the like or an optically transmissive member in a plate shape that diffuses light beams emitted from a light source to reduce illumination unevenness. In the case in which such a coaxial illuminator is used as a lighting device for surface inspection, in some cases, a small enough point light source is not obtained even though the LEDs 261a are separately lit. Therefore, as shown in FIG. 17A, a side plate 261d may be provided between the LED substrate 261b and the diffuser 261c so as not to spread the application light beam of the LED 261a for suppressing blurs in the diffuser 261c.

Second Exemplary Modification

A coaxial illuminator according to a second exemplary modification will be described with reference to FIGS. 16 and 17B.

As shown in FIG. 17B, instead of the diffuser 261c shown in FIG. 16, a liquid crystal panel 261e, which is a dynamic diffuser, may be installed. At the time of alignment, the liquid crystal panel 261e is controlled to be whitish for diffuse emission. At the time of surface inspection, in order to provide a point light source by separately lighting LEDs, the liquid crystal panel 261e is controlled to be transparent. Thus, it is possible to use the same lighting device at the time of alignment and at the time of surface inspection.

Third Exemplary Modification

A coaxial illuminator according to a third exemplary modification will be described with reference to FIG. 18. A two-layer structure may be provided in which a box-type coaxial illuminator shown in FIG. 14 is laid on a box-type alignment coaxial illuminator shown in FIG. 16. The coaxial illuminator shown in FIG. 14 may be disposed below the coaxial illuminator shown in FIG. 16, or may be disposed above.

Fourth Exemplary Modification

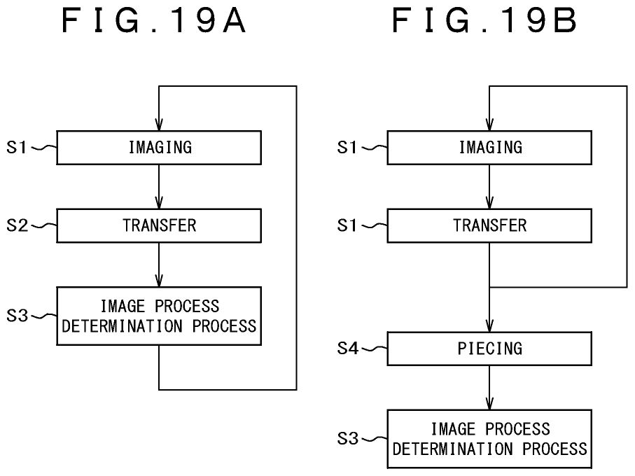

The operation of a bright-field inspection system according to a fourth exemplary modification will be described with reference to FIGS. 19A and 19B.

As shown in FIGS. 15 and 19A, in the present embodiment, imaging (S1), transfer (S2), and the image process and the determination process (S3) are repeated for the number of inspection areas. In the fourth exemplary modification, as shown in FIG. 19B, imaging (S1) and transfer (S2) are repeated for the number of inspection areas, images of the inspection areas are pieced together (S4), and then the image process and the determination process (S3) are performed for batch inspection. However, at this time, additive synthesis in which data (pixel value) of the inspected area at each capture is added is allowed. This is because when the data of the inspected area is mixed, this creates an image when a surface emitting coaxial illuminator is simply applied.

### Second Embodiment

The configuration of a die bonder according to the present embodiment and the configuration of a control system are configurations similar to the die bonder according to the first embodiment. A die bonding process according to the present embodiment is a process similar to the die bonding process according to the first embodiment.

In order to more clearly define an illuminator for surface inspection according to the present embodiment, problems in the illuminator to detect flaws will be described.

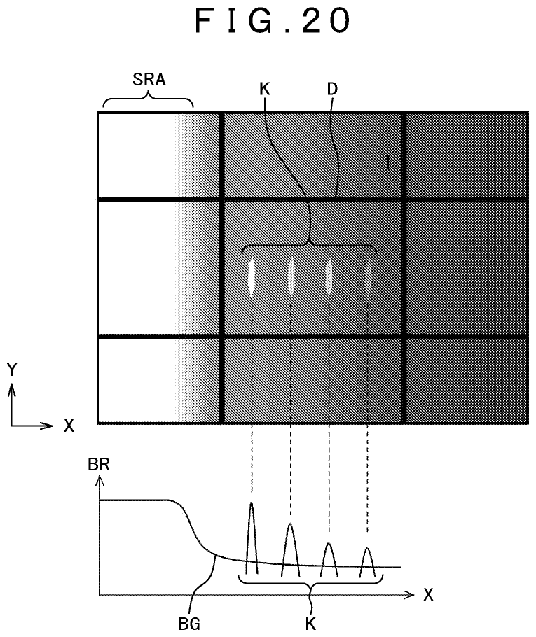

A dark-field inspection system using a dark field method in a comparative example of the present embodiment will be described with reference to FIGS. 4 and 20.

As described in the first embodiment, surface inspection (dark-field inspection) in the dark-field inspection system shown in FIG. 4 is performed in an area other than the specular reflection area SRA derived from the installation position of the oblique light bar illuminator. As shown in FIG. 20, a specular reflection area SRA has a rectangular shape having a length in the Y-axis direction longer than a length in the X-axis direction.

The specular reflection area SRA is formed on the surrounding dies Dp adjacent on the left side of the die D that is an inspection target. In dark-field inspection, a flaw is visualized by reflecting light on the side surface (in the inside) of a micro flaw. In the case in which a flaw such as a crack continuously and linearly occurs, its side surface also continues, and the flaw is visualized, the visualization depending on the application direction of the illumination light beam IL. Therefore, in the horizontal direction, the illumination light beam IL is applied from the direction different from the direction in which the flaw extends, and thus light is applied to the side surface.

As shown in an image on the upper side of FIG. 20, although flaws K extending along the Y-axis direction are recognizable, the flaws K are gradually darker toward the X-axis direction. As shown in a graph of the lightness (BR) on the lower side of FIG. 20, since the contrast ratio of the background BG to the flaw K increases as closer to the specular reflection area SRA, sensitivity becomes the highest in areas close to the specular reflection area SRA. In other words, inspection sensitivity is degraded as separated from the specular reflection area SRA.

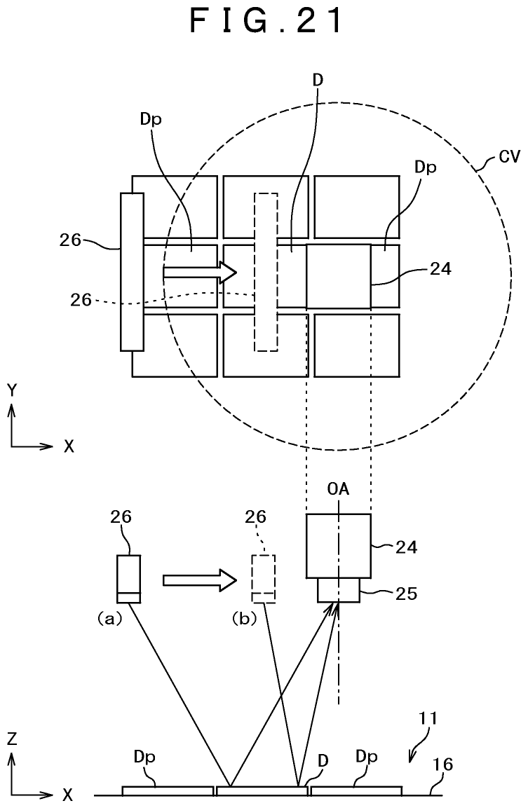

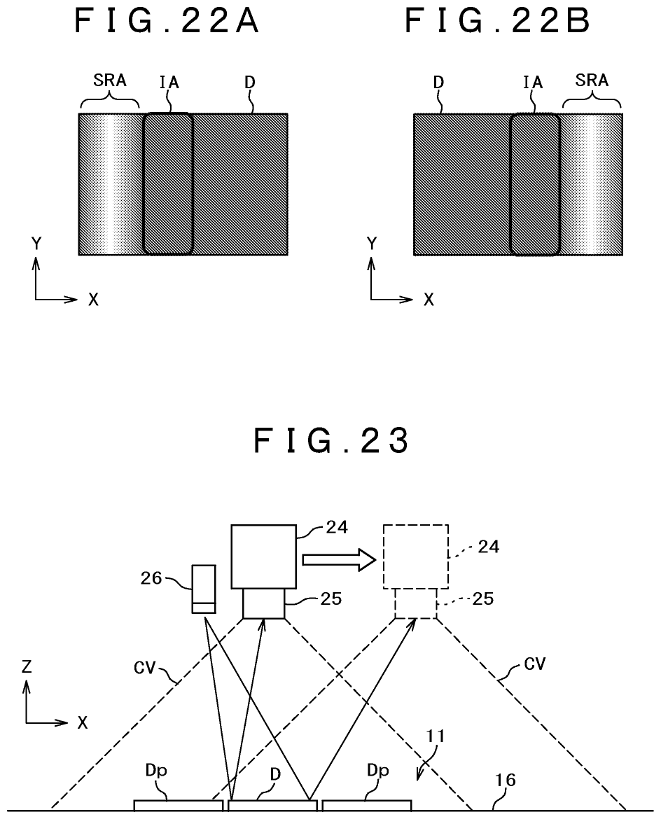

A dark-field inspection system according to the present embodiment will be described, taking an example of the optical system of a pickup unit with reference to FIGS. 21, 22A, and 22B.

As shown in FIG. 21, a wafer recognition camera 24 attached with a lens 25 is disposed perpendicular to the surface of a wafer 11 (die D). That is, an optical axis OA is set perpendicular to the surface of the die D. However, the wafer recognition camera 24 is disposed at a position apart from the center of the die D that is an imaging target. A lighting device 26 is a bar illuminator, and its light-emitting face is disposed opposite to the surface of the wafer 11. Although the lighting device 26 emits light in the direction along the optical axis OA, illumination light beams to be applied are diffused light beams, and have a spread in the application direction (the application area on the surface of the wafer 11). The light-emitting face of the lighting device 26 has a rectangular shape in which the length in the Y-axis direction is longer than the length in the X-axis direction. In other words, the lighting device 26 extends in the Y-axis direction. The width of the light-emitting face of the lighting device 26 (the length in the X-axis direction) is shorter than the width of the lens 25. The lighting device 26 is disposed at a position that is not included in a visual field CV of the wafer recognition camera 24, at a position at a height equivalent to the undersurface of the lens 25, for example.

The lighting device 26 is movable along the X-axis direction. The visual field of the wafer recognition camera 24 is wider than the die D.

As shown in FIG. 21, a controller 8 moves the lighting device 26 in the X-axis direction by a drive unit, not shown, and moves the position of the specular reflection area SRA. When the lighting device 26 moves at a position (a) shown in FIG. 21, as shown in FIG. 22A, the specular reflection area SRA moves, and the controller 8 images the die D at that position. In the captured image, the controller 8 subjects an inspection area IA adjacent on the right side of the specular reflection area SRA (in the moving direction side of the specular reflection area SRA) to image processing for inspection. The inspection area IA as a predetermined area has a predetermined size, and is the highly sensitive area in the dark-field inspection. The inspection area IA is a part of a dark field area formed on the die D, which has a size equivalent to the specular reflection area SRA, for example. Note that in the case of setting an area near the left end part of the die D as the inspection area IA, the specular reflection area SRA is located near the left outer side of the die D.

When the lighting device 26 moves to a position between (a) and (b) shown in FIG. 21, the specular reflection area SRA moves to the center part of the die D, and the controller 8 images the die D at that position. In the captured image, the controller 8 subject two inspection areas IA, which are close to the specular reflection area SRA and sandwich the specular reflection area SRA, to image processing for inspection.

When the lighting device 26 moves to the position (b) shown in FIG. 21, as shown in FIG. 22B, the specular reflection area SRA moves, and the controller 8 images the die D at that position. In the captured image, the controller 8 subjects the inspection area IA adjacent on the left side of the specular reflection area SRA (on the opposite side of the moving direction of the specular reflection area SRA) to image processing for inspection. Note that in the case of setting an area near the right end part of the die D as the inspection area IA, the specular reflection area SRA is located near the right outer side of the die D.

The controller 8 repeats moving the lighting device 26, imaging the die D by the wafer recognition camera 24, and inspection by image processing, and thus it is possible to provide the area of the highest sensitivity on the entire die D for inspection.

The optical system of the pickup unit 2 (the wafer recognition camera 24 and its lighting device 26) has been described. The optical system of the intermediate stage unit 3 (the stage recognition camera 32 and its lighting device) and the optical system of the bonding unit 4 (the substrate recognition camera 44 and its lighting device) also have similar configurations. According to the present embodiment, since it is possible to move the specular reflection area for inspection, it is possible to improve the detection sensitivity of a flaw. Since the detection sensitivity of a flaw is improved, it is possible to improve the yields of a product assembled by the die bonder.

Exemplary modifications of second embodiment

In the following, some representative exemplary modifications of the present embodiment will be described. In the description of the exemplary modifications below, it is assumed that components having similar configurations and functions as ones described in the present embodiment are designated with similar reference signs of the embodiments described above. In the description of these components, within a scope technically consistent, the description of the embodiment is to be appropriately incorporated by reference. A part of the embodiment and all or some of a plurality of exemplary modifications are to be appropriately incorporated within a scope technically consistent.

First Exemplary Modification

A dark-field inspection system according to a first exemplary modification will be described with reference to FIG. 23.

In the present embodiment, in order to move the position of the specular reflection area SRA, the lighting device 26 is moved in the horizontal direction. In the first exemplary modification, the wafer recognition camera 24 is horizontally moved. In the case of moving the wafer recognition camera 24, the position of the wafer 11 (die D) moves in the visual field CV of the wafer recognition camera 24, and the specular reflection positions of illumination light beams reaching the wafer recognition camera 24 on the wafer 11 (die D) also change.

Second Exemplary Modification

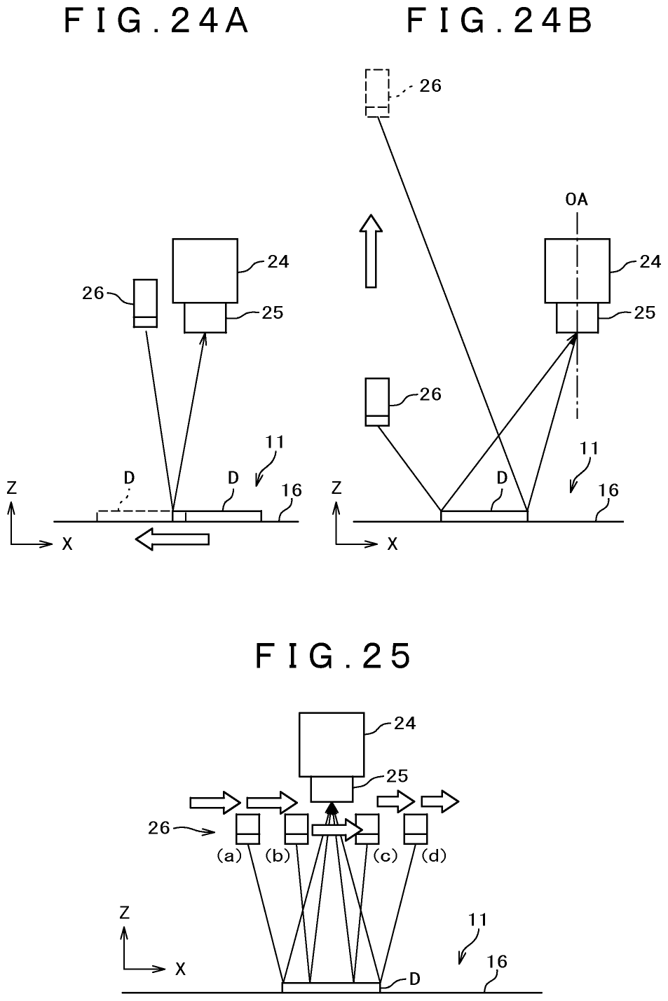

A dark-field inspection system according to a second exemplary modification will be described with reference to FIG. 24A.

In the present embodiment, in order to move the position of the specular reflection area SRA, the lighting device 26 is moved in the horizontal direction. In the second exemplary modification, as shown in FIG. 24A, the wafer 11 (die D) that is a subject is horizontally moved. Thus, the specular reflection positions of illumination light beams reaching the wafer recognition camera 24 on the wafer 11 (die D) change.

Third Exemplary Modification

A dark-field inspection system according to a third exemplary modification will be described with reference to FIG. 24B.

In the third exemplary modification, as shown in FIG. 24B, the lighting device 26 is moved in the direction along the optical axis OA (the vertical direction to the surface of the wafer 11 (die D)). Thus, the specular reflection positions of illumination light beams reaching the wafer recognition camera 24 on the wafer 11 (die D) change.

Fourth Exemplary Modification

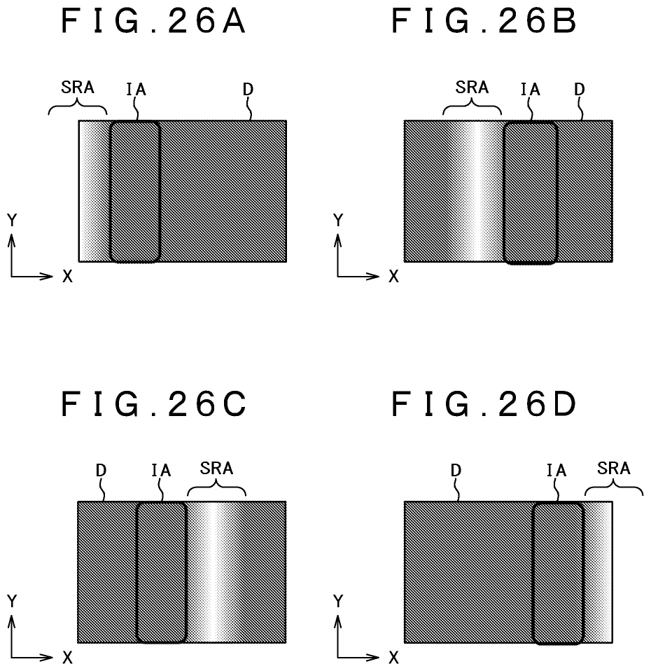

A dark-field inspection system according to a fourth exemplary modification will be described with reference to FIGS. 25, and 26A to 26D.

In the present embodiment, the wafer recognition camera 24 is disposed at a position apart from the center of the die D that is an imaging target. In the fourth exemplary modification, as shown in FIG. 25, the wafer recognition camera 24 is disposed near the center of the die D that is an imaging target, and the lighting device 26 is disposed at a position passable under the wafer recognition camera 24 (lens 25).

In the following, the operation in the case in which the lighting device 26 moves from the left side of the wafer recognition camera 24 to the right side along the X-axis direction (the lateral direction), and passes under the wafer recognition camera 24 will be described.

First, the lighting device 26 is disposed such that the specular reflection area SRA is located near the left outer side of the die D. In this case, an area near the left end part of the die D, i.e., on the right side of the specular reflection area SRA is set as the inspection area IA.

When the lighting device 26 having moved from the left side moves to a position (a) shown in FIG. 25, as shown in FIG. 26A, the specular reflection area SRA is formed near the left end part of the die D. At this position, the right side of the specular reflection area SRA is set as the inspection area IA.

During a period in which the lighting device 26 moves to a position (b) shown in FIG. 25 (the position near the left end of the lens 25), as shown in FIG. 26B, the right side of the specular reflection area SRA is set as the inspection area IA. Here, the position (b) shown in FIG. 25 is a boundary position at which the inspection area IA is not shielded by the lighting device 26.

From the position (b) shown in FIG. 25 to a position (c), the lighting device 26 enters the inside of the visual field of the wafer recognition camera 24, and the lighting device 26 alone moves without imaging of the die D.

Subsequently, when the lighting device 26 moves at the position (c) shown in FIG. 25 (the position near the left end of the lens 25), as shown in FIG. 26C, the left side of the specular reflection area SRA is set as the inspection area. Here, the position (c) shown in FIG. 25 is a boundary position at which the inspection area IA is not shielded by the lighting device 26.

When the lighting device 26 moves to a position (d) shown in FIG. 25, as shown in FIG. 26D, the specular reflection area SRA is formed near the right end part of the die D. Also in this case, the left side of the specular reflection area SRA is set as the inspection area IA.

The lastly, the lighting device 26 is disposed such that the specular reflection area SRA is located near the right outer side of the die D. Also in this case, an area near the right end part of the die D, i.e., the left side of the specular reflection area SRA is set as the inspection area IA. Thus, it is possible to inspect the entire surface of the die D.

Fifth Exemplary Modification

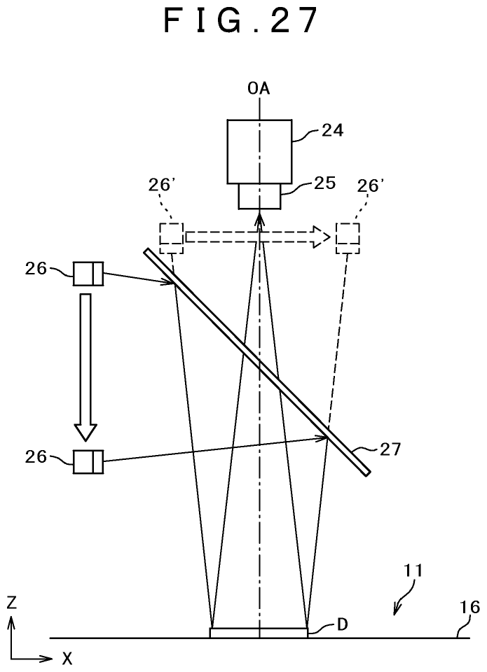

A dark-field inspection system according to a fifth exemplary modification will be described with reference to FIG. 27.

In the fourth exemplary modification, since the lighting device 26 is located below the wafer recognition camera 24, the lighting device 26 sometimes enters the inside of the visual field of the wafer recognition camera 24. In this case, one of two areas adjacent to the specular reflection area SRA fails to be set as the inspection area. For example, in the case in which the lighting device 26 moves at the position (b) shown in FIG. 25, although the right side of the specular reflection area SRA shown in FIG. 26B can be set as the inspection area IA, the left side of the specular reflection area SRA fails to be set as the inspection area.

In the fifth exemplary modification, the wafer recognition camera 24 attached with the lens 25 is disposed perpendicular to the surface of the die D that is an imaging target. That is, the wafer recognition camera 24 is installed such that the optical axis OA is located near the center of the surface of the die D and the optical axis OA is perpendicular to the surface of the die D. Between the lens 25 and the die D, a half mirror 27 is installed, being inclined at an angle of 45 degrees to the optical axis OA of the wafer recognition camera 24. The lighting device 26 is disposed on the outer side of the visual field of the wafer recognition camera 24, and the light-emitting face of the lighting device 26 is disposed opposite to the half mirror 27. The lighting device 26 is movable along the optical axis OA in the direction.

The controller 8 controls the lighting device 26 to move in the vertical direction such that a virtual lighting device 26′ similarly moves as the lighting device 26 shown in FIG. 25. Since the lighting device 26 is located on the outer side of the visual field of the wafer recognition camera 24, one of two areas adjacent to the specular reflection area SRA can be set as the inspection area. Even in the case in which the virtual lighting device 26′ is located right under the lens 25 or near the outer side of the left and right end parts, imaging is possible.

Sixth Exemplary Modification

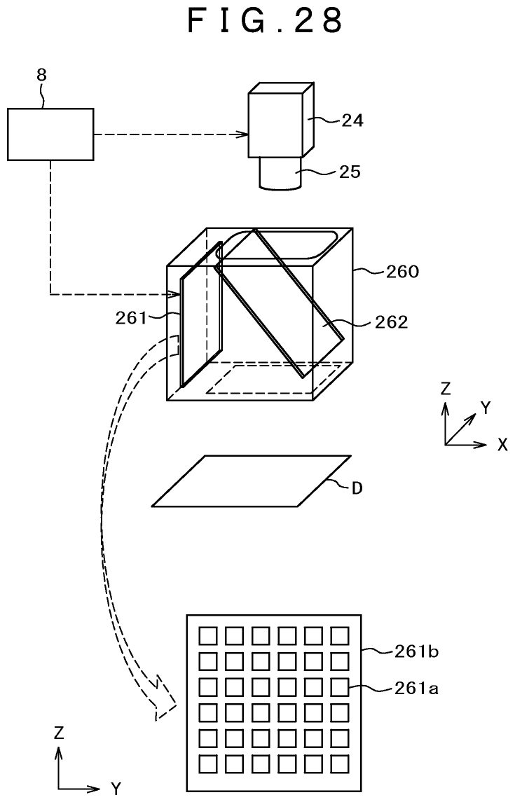

A dark-field inspection system according to a sixth exemplary modification will be described with reference to FIG. 28.

In the sixth exemplary modification, between the lens 25 and the die D on a line connecting the wafer recognition camera 24 to the die D, the lighting device 260 including the surface emitting illuminator (light source) 261 and the half mirror (semi-transmissive mirror) 262 in its inside is disposed. Application light beams from the surface emitting illuminator 261 are reflected by the half mirror 262 at the optical axis the same as the wafer recognition camera 24, and applied to the die D. The scattered light beams applied to the die D at the optical axis the same as the wafer recognition camera 24 are reflected off the die D, and the specularly reflected light beams of the scattered light beams transmit the half mirror 262, and reach the wafer recognition camera 24 to form an image of the die D. That is, the lighting device 260 has the function of the coaxial epi-illuminator (coaxial illuminator).

The surface emitting illuminator 261 in the lighting device 260 is a surface emitting LED light source, and includes an LED substrate 261b having a plurality of LEDs 261a as point light sources arrayed on a plane in a grid shape. The LEDs 261a are individually formed to turn on (ON) and turn off (OFF).

At the time of surface inspection, the controller 8 is configured such that the LED 261a is sequentially turned on at every column or every row to form a line light source for moving the line light source. The application area of the half mirror 262 of the surface emitting illuminator 261 is narrowed, and thus the specular reflection area SRA and the inspection area IA for the dark field are provided. The controller 8 is configured such that at the time of alignment, all the LEDs 261a of the lighting device 26 are turned on.

As described above, the disclosure made by persons of the present disclosure has been described based on the embodiments and the exemplary modifications. The present disclosure is not limited to the embodiments and the exemplary modifications, and it goes without saying that the present disclosure can be modified variously.

For example, in the embodiment, an example is described in which in the coaxial illuminator, LEDs arranged in a matrix configuration are sequentially turned on. However, LEDs as a point light source may be moved.

In the embodiment, an example is described in which in the coaxial illuminator, the line light source is moved while LEDs arranged in a matrix configuration are sequentially turned on. However, the bar illuminator as a line light source may be moved.

In the embodiment, an example is described in which a macro lens is used. However, a telecentric lens may be used.

In the embodiment, the description is made taking an example of die bonder (semiconductor manufacturing apparatus) that places a die on a substrate. However, the embodiment is also applicable to an inspection apparatus that inspects the surface of a wafer (die) before being loaded into a die bonder or an inspection apparatus that inspects the surface of a die placed on a substrate unloaded from a die bonder.

In the embodiment, die appearance inspection recognition is performed after die position recognition. However, die position recognition may be performed after die appearance inspection recognition.

In the embodiment, a DAF is attached to the back surface of the wafer. However, the DAF may be eliminated.

In the embodiment, one pickup head and one bonding head are provided. However, two or more pickup heads and two or more bonding heads may be provided. In the embodiment, the intermediate stage is included. However, the intermediate stage may be eliminated. In this case, the pickup head may serve as the bonding head.

In the embodiment, the die is bonded as the front surface of the die is the upside. However, it is possible that after a die is picked up, the front and the back side are reversed, and the back surface of the die is the upside for bonding. In this case, the intermediate stage may be eliminated. This apparatus is referred to as a flip chip bonder.

In the embodiment, the description is made taking an example of a die bonder (semiconductor manufacturing apparatus) that places a die on a substrate. However, the embodiment is also applicable to an inspection apparatus that inspects the surface of a wafer (die) before being loaded into a die bonder or an inspection apparatus that inspects the surface of a die placed on a substrate unloaded from a die bonder.

Additional Remarks

In the following, preferable aspects of the present disclosure will be additionally noted.

Additional Remark 1

A semiconductor manufacturing apparatus including:

an imaging device that images a die;

a lens provided on the imaging device;

a lighting device that applies an illumination light beam; and

a controller configured to form a specular reflection area on a die or in surroundings of the die by the lighting device, form a dark field area larger than the specular reflection area on the die at time of surface inspection, and repeat moving the specular reflection area at a predetermined pitch and imaging the die to inspect a predetermined area close to the specular reflection area in the dark field area.

Additional Remark 2

In the semiconductor manufacturing apparatus of additional remark 1, the controller is configured to inspect a predetermined area close to a side of a moving direction of the specular reflection area, or a predetermined area close to an opposite side of the moving direction of the specular reflection area, or a predetermined area close to both sides of the specular reflection area, based on a site where the specular reflection area is located.

Additional Remark 3

In the semiconductor manufacturing apparatus of additional remark 2, the controller inspects, when the specular reflection area is located on a side of one end of the die, a predetermined area close to a side of the moving direction of the specular reflection area; and the controller inspects, when the specular reflection area is located on a side of another end of the die, a predetermined area close to the opposite side of the moving direction of the specular reflection area.

Additional Remark 4

In the semiconductor manufacturing apparatus of additional remark 2, when the specular reflection area is located near a center part of the die, the controller is configured to inspect a predetermined area close to both sides of the specular reflection area.

Additional Remark 5

In the semiconductor manufacturing apparatus of additional remark 1,

the lighting device is a bar illuminator having a light-emitting face in which a first direction is longer than a second direction, and the lighting device is provided such that an application light beam is applied to a third direction along an optical axis of the imaging device; and

the controller is configured to move the specular reflection area by moving the lighting device in the second direction.

Additional Remark 6

In the semiconductor manufacturing apparatus of additional remark 1,

the lighting device is a bar illuminator having a light-emitting face in which a first direction is longer than a second direction, and the lighting device is provided being fixed such that an application light beam is applied in a third direction along an optical axis of the imaging device; and

the controller is configured to move the specular reflection area by moving the imaging device in the second direction.

Additional Remark 7

In the semiconductor manufacturing apparatus of additional remark 1,

the lighting device is a bar illuminator having a light-emitting face in which a first direction is longer than a second direction, and the lighting device is provided being fixed such that an application light beam is applied in a third direction along an optical axis of the imaging device; and

the controller is configured to move the specular reflection area by moving the die in the second direction.

Additional Remark 8

In the semiconductor manufacturing apparatus of additional remark 1,

the lighting device is a bar illuminator having a light-emitting face in which a first direction is longer than a second direction, and the lighting device is provided such that an application light beam is applied to a third direction along an optical axis of the imaging device; and

the controller is configured to move the specular reflection area by moving the lighting device in a direction along an optical axis of the imaging device.

Additional Remark 9

In the semiconductor manufacturing apparatus of additional remark 5 or 8, the imaging device is disposed being offset on an outer side from an end part of the die. Additional remark 10

In the semiconductor manufacturing apparatus of additional remark 5,

the imaging device is disposed on the die;

the lighting device is disposed so as to pass under the imaging device; and

when the lighting device is located below the lens, the controller is configured so as not to image the die.

Additional Remark 11

In the semiconductor manufacturing apparatus of additional remark 1,

a half mirror is further included between the imaging device and the die;

the lighting device is a bar illuminator having a light-emitting face in which a first direction is longer than a third direction, and the lighting device is provided such that an application light beam is applied to the half mirror disposed in a second direction perpendicular to an optical axis of the imaging device;

the imaging device is disposed on the die; and

the controller is configured to move the specular reflection area by moving the lighting device in the third direction along a direction of an optical axis of the imaging device.

Additional Remark 12

In the semiconductor manufacturing apparatus of additional remark 1,

the lighting device is disposed between the imaging device and the die, and the lighting device includes a surface emitting illuminator and a half mirror;

the surface emitting illuminator includes a plurality of LEDs disposed flat in a matrix configuration, and the LEDs are operable to individually turn on and turn off; and the controller is configured to light LEDs in one column or one row of the plurality of LEDs at time of surface inspection.

Additional Remark 13

In the semiconductor manufacturing apparatus of additional remark 12, the controller is configured to move the specular reflection area by changing a lighting site of the LED.

Additional remark 14

An inspection apparatus including:

an imaging device that images a die;

a lens provided on the imaging device; a lighting device that applies an illumination light beam; and

a controller configured to form a specular reflection area on a die or in surroundings of the die by the lighting device, form a dark field area larger than the specular reflection area on the die at time of surface inspection, and repeat moving the specular reflection area at a predetermined pitch and imaging the die to inspect a predetermined area close to the specular reflection area in the dark field area.

Additional Remark 15

A manufacturing method for a semiconductor device including the steps of:

loading a wafer ring holding plurality of dies in a wafer shape into a semiconductor manufacturing apparatus including an imaging device that images a die, a lens provided on the imaging device, and a lighting device that applies an illumination light beam; and

forming a specular reflection area on a die or in surroundings of the die by the lighting device, forming a dark field area larger than the specular reflection area on the die at time of surface inspection, and repeating moving the specular reflection area at a predetermined pitch and imaging the die to inspect a predetermined area close to the specular reflection area in the dark field area.

What is claimed is:

1. A semiconductor manufacturing apparatus comprising:
an imaging device that images a die;
a lighting device having a light source that is a point light source or a line light source; and
a controller configured to apply a light beam to a part of the die by the light source to form a bright field area on the die, and repeat moving the bright field area at a predetermined pitch and imaging of the die to inspect an inside of the bright field area.

2. The semiconductor manufacturing apparatus according to claim 1, wherein the controller is configured to move the bright field area by moving a light-emitting position of the light source.

3. The semiconductor manufacturing apparatus according to claim 1, wherein the controller is configured to move the bright field area by moving the die.

4. The semiconductor manufacturing apparatus according to claim 1, wherein the controller is configured to move the bright field area by moving the imaging device.

5. The semiconductor manufacturing apparatus according to claim 1, wherein the controller is configured to move the bright field area with an overlap.

6. The semiconductor manufacturing apparatus according to claim 1, wherein the controller is configured to perform bright field inspection with the bright field area and perform dark-field inspection with a dark field area adjacent to the bright field area.

7. The semiconductor manufacturing apparatus according to claim 1, wherein the controller is configured to, after transfer of image data of first bright field area by the imaging device, perform an image process and a determination process of the first bright field area in parallel with transfer of image data of a subsequent bright field area by the imaging device.

8. The semiconductor manufacturing apparatus according to claim 1,
wherein a half mirror disposed between the imaging device and the die is further provided; and
the light source is configured to make application onto the die through the half mirror.

9. The semiconductor manufacturing apparatus according to claim 1,
wherein the lighting device is disposed between the imaging device and the die, and the lighting device includes a surface emitting illuminator and a half mirror;
the surface emitting illuminator includes a plurality of LEDs disposed flat in a matrix configuration, and the LEDs are operable to individually turn on and turn off; and
the controller is configured to light some of the plurality of LEDs to form the point light source or the line light source.

10. The semiconductor manufacturing apparatus according to claim 9, wherein the controller is configured to change a lighting site of the LED to move the point light source or the line light source.

11. The semiconductor manufacturing apparatus according to claim 10, wherein the controller is configured to light all the plurality of LEDs at time of alignment.

12. The semiconductor manufacturing apparatus according to claim 11, the lighting device further comprising:
a diffuser provided between the surface emitting illuminator and the half mirror; and
a side plate provided between the surface emitting illuminator and the diffuser.

13. The semiconductor manufacturing apparatus according to claim 11, wherein the lighting device further includes a liquid crystal panel provided between the surface emitting illuminator and the half mirror.

14. The semiconductor manufacturing apparatus according to claim 10, further comprising a second lighting device disposed between the imaging device and the die, the second lighting device including a surface emitting illuminator, a half mirror, and a diffuser provided between the surface emitting illuminator and the half mirror.

15. The semiconductor manufacturing apparatus according to claim 1, wherein the controller is configured to, after the imaging device repeats imaging a bright field area and transfer of image data for a number of bright field areas, piece images of the bright field areas together and perform an image process and a determination process of the images pieced together for batch inspection.

16. An inspection apparatus comprising:
an imaging device that images a die;
a lighting device having a light source that is a point light source or a line light source; and
a controller configured to apply a light beam to a part of the die by the light source to form a dark field area on the die, form a bright field area smaller than the dark field area on the die, and repeat moving the bright field area at a predetermined pitch and imaging the die to inspect an inside of the bright field area.

17. A manufacturing method for a semiconductor device comprising the steps of:
loading a wafer ring holding a plurality of dies in a wafer shape into a semiconductor manufacturing apparatus including an imaging device that images a die, and a lighting device having a light source that is a point light source or a line light source; and
applying a light beam to a part of the die by the light source to form a bright field area, and repeat moving the bright field area at a predetermined pitch and imaging the die to inspect an inside of the bright field area.
